(19) United States
(12) Patent Application Publication
(10) Pub. No.: US 2007/0088892 A1
(43) Pub. Date: Apr. 19, 2007

(54) Control unit connectable to expansion unit

(75) Inventor: Noriaki Ikeda, Hachioji-shi (JP)

Correspondence Address: FINNEGAN, HENDERSON, FARABOW, GARRETT & DUNNER;LLP, 901 NEW YORK AVENUE, NW, WASHINGTON, DC, 20001-4413, US

(73) Assignee: KABUSHIKI KAISHA TOSHIBA

(21) Appl. No.: 11/526,728

(22) Filed: Sep. 26, 2006

(30) Foreign Application Priority Data
Oct. 19, 2005 (JP) 2005-304722

(51) Int. Cl. H05K 7/10

(52) U.S. Cl. 710/301

(57) ABSTRACT

According to one embodiment, a connection detection circuit detects a first state in which a first connector is connected to a motherboard. A reset-releasing circuit releases the reset state of a control unit upon detection of the first state by the connection detection circuit. The reset-releasing circuit receives a particular signal from an expansion unit via a particular signal pin. The particular signal pin assumes a particular logical state in a second state in which the expansion unit is connected to the motherboard. When the logical state of the particular signal pin differs from the particular logical state, the reset-releasing circuit does not release the reset state of the control unit, regardless of whether the connection detection circuit detects the first state.

### CROSS-REFERENCE TO RELATED APPLICATIONS

This application is based upon and claims the benefit of priority from Japanese Patent Application No. 2005-304722, filed Oct. 19, 2005, the entire contents of which are incorporated herein by reference.

### BACKGROUND

1. Field

One embodiment of the invention relates to an information processing apparatus with a control unit used connected to a motherboard, and more particularly to a control unit connectable to an expansion unit and suitable for mounting the expansion unit on the information processing apparatus for function extension.

2. Description of the Related Art

In general, information processing apparatuses represented by private branch exchanges (PBXs) are provided with a plurality of printed circuit boards including a control unit (control board) for controlling the entire apparatus. These boards are generally connected to the motherboard using connectors.

In information processing apparatuses of this type, there is a case where the functionality of the control unit needs to be extended. In general, to extend the functionality of the control unit, an expansion unit (expansion board) is used. In the prior art, during control unit expansion work, the expansion unit is connected to the motherboard and control unit, using connectors, whereby it is mounted on the information processing apparatus. In this state, the control unit and expansion unit cooperate to exhibit extended control functionality. In this prior art (first prior art), when the control unit is correctly connected to the motherboard, it is automatically released from its reset state and becomes operable upon the turn-on of the apparatus.

On the other hand, Jpn. Pat. Appln. KOKAI Publication No. 2003-318576 (prior art document), for example, discloses an information processing system in which a monitor board and interface board are connected to a motherboard (backplane) via connectors. In the technique (second prior art) described in this document, the monitor board always or regularly monitors the operation state of the interface board. The CPU section on the monitor board determines whether the interface board is correctly connected to the motherboard, depending upon whether the potential of a preset line is high (H). If the interface board is not correctly connected to the motherboard, the monitor board determines that no interface board exists. In contrast, if the interface board is correctly connected to the motherboard, the monitor board and interface board hold mount information indicating this fact. Based on the mount information, the control section on the interface board releases the reset state of the circuit mounted on the interface board, under the control of the CPU section of the monitor board.

Because of incorrect control unit expansion work, an incomplete connection state may occur in which, for example, the expansion unit is connected to the control unit, but not to the motherboard. Even in such an incomplete connection state, however, in the first prior art, the reset state of the control unit is released if the control unit is correctly connected to the motherboard. In this case, since the control unit is operable, it is difficult for the worker to correctly determine whether the control unit expansion work is completed.

On the other hand, in the second prior art, the monitor board can determine whether the interface board is correctly connected to the motherboard. It is possible to impart the determination function of the monitor board to the control unit of the first prior art in order to enable the control unit to determine whether the expansion unit is correctly connected to the motherboard. In this case, when the expansion unit is not correctly connected to the motherboard, the control unit is prevented from being released from its reset state.

However, in the technique acquired by applying the second prior art to the first prior art, the control unit may operate in the following manner. Namely, even if the control unit is used singly without any expansion unit, the control unit determines that the expansion unit is not correctly connected to the motherboard, with the result that the reset state of the control unit is not released.

### BRIEF DESCRIPTION OF THE SEVERAL VIEWS OF THE DRAWINGS

A general architecture that implements the various feature of the invention will now be described with reference to the drawings. The drawings and the associated descriptions are provided to illustrate embodiments of the invention and not to limit the scope of the invention.

FIG. 1 is a block diagram illustrating an exemplary configuration of the essential part of a private branch exchange according to a first embodiment of the invention;

FIG. 2 is a perspective view illustrating an exemplary mount structure of the peripheral portion of a motherboard employed in the private branch exchange of FIG. 1; and

FIG. 3 is a block diagram illustrating an exemplary configuration of the essential part of a private branch exchange according to a second embodiment of the invention.

### DETAILED DESCRIPTION

Various embodiments according to the invention will be described hereinafter with reference to the accompanying drawings. In general, according to one embodiment of the invention, there is provided a control unit permitted to be connected to a motherboard, and permitted to extend functionality thereof when the control unit is connected to an expansion unit. The control unit comprises a first connector to be connected to the motherboard; a connection detection circuit which detects a first state in which the first connector is connected to the motherboard; a second connector to be connected to the expansion unit and including a particular signal pin, the particular signal pin receiving, from the expansion unit, a particular signal which assumes a particular logical state in a second state in which the expansion unit is connected to the motherboard; a state-setting unit which sets the particular signal pin to the particular logical state when the particular signal is not sent to the particular signal pin; and a reset-releasing circuit which releases the control unit from a reset state upon detection of the first state by the connection detection circuit, the reset-releasing circuit preventing the reset state of the control unit from being released regardless of whether the connection detection circuit detects the first state, when the particular signal pin assumes a logical state different from the particular logical state.

Embodiments of the invention will be described with reference to the accompanying drawings.

### FIRST EMBODIMENT

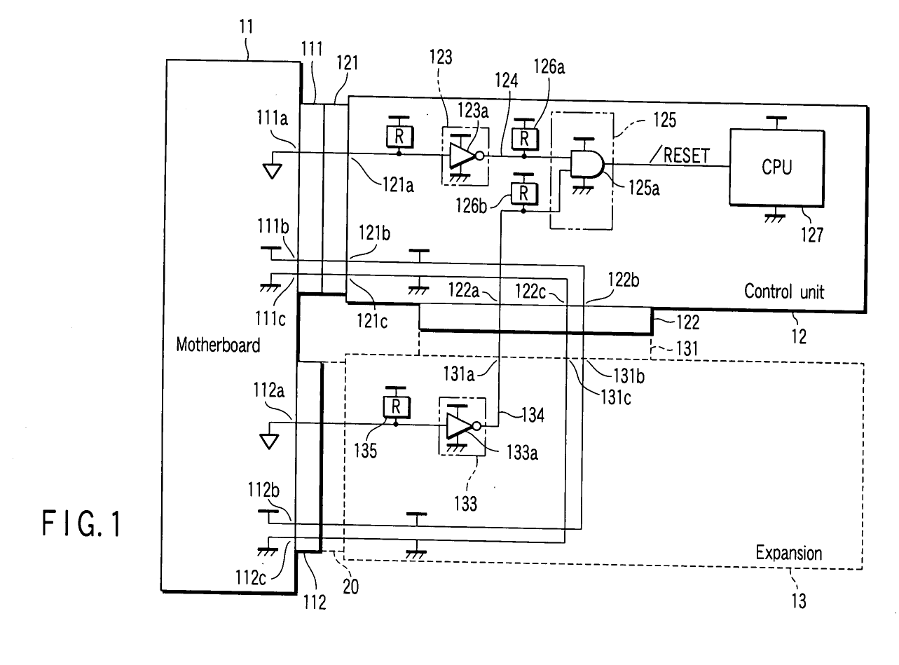

FIG. 1 shows an exemplary configuration of the essential part of a private branch exchange according to a first embodiment of the invention. In FIG. 1, one connector 111 of a motherboard 11 is connected to one connector (first connector) 121 of a control unit 12. The motherboard 11 is also connected to an interface unit (not shown) to be controlled by the control unit 12.

The connector 121 of the control unit 12 includes signal pins for connecting the control unit 12 to the motherboard 11. The control unit 12 has, as well as the connector 121, a connector (second connector) 122 that includes signal pins for connecting the control unit 12 to an expansion unit 13. When the control unit 12 is connected to a connector 131 included in the expansion unit 13 via the connector 122, it extends its functionality. In this case, however, it is necessary to also connect the expansion unit 13 to the other connector 112 of the motherboard 11 via a connector section 20 included in the expansion unit 13. Namely, the expansion unit 13 is constructed to extend the functionality of the control unit 12 when it is connected to the motherboard 11 and control unit 12.

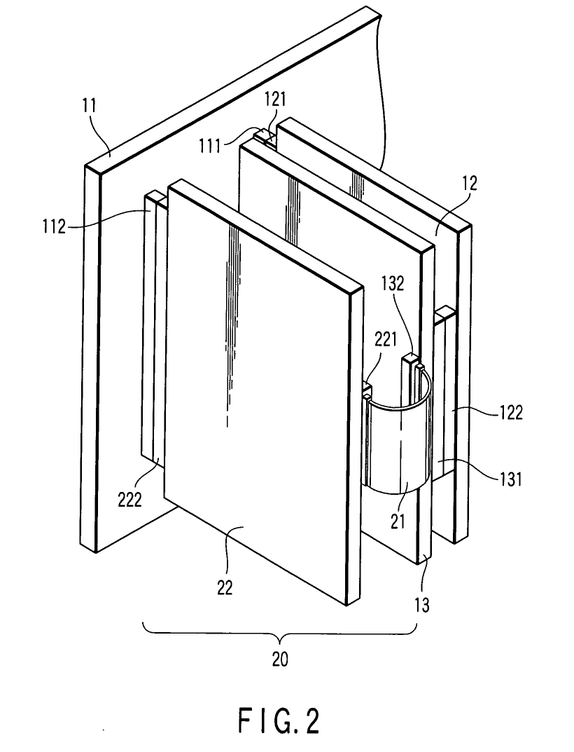

FIG. 2 shows an exemplary mount structure of the peripheral portion of the motherboard 11 in the private branch exchange of FIG. 1. The connector section 20 comprises the other connector 132 of the expansion unit 13, a flexible printed circuit board (FPC board) 21, and an extension board 22. The extension board 22 includes connectors 221 and 222. The connectors 122 and 131 of the control unit 12 and expansion unit 13 are provided on surfaces of the control unit 12 and expansion unit 13, respectively, so that the control unit 12 and expansion unit 13 can be connected with their surfaces opposing each other.

To mount the expansion unit 13 on the motherboard 11, the connector 132 of the expansion unit 13 is connected to the connector 221 of the extension board 22 by the FPC board 21, and the connector 222 of the extension board 22 is connected to the connector 112 of the motherboard 11, whereby the expansion unit 13 is connected to the connector 112 of the motherboard 11 via the connector section 20. In the first embodiment, the connector section 20 is used to mount the expansion unit 13 on the motherboard 11 in light of the restricted mount space of the expansion unit 13. However, the expansion unit 13 can be directly connected to the motherboard 11 using a connector similar to the connector 121 of the control unit 12.

Referring again to FIG. 1, the connector 121 of the control unit 12 includes signal pins 121a, 121b and 121c. The signal pins 121a, 121b and 121c are connected to a ground pin 111a, power supply pin 111b and ground pin 111c of the connector 111 of the motherboard 11, respectively.

In the control unit 12, the signal pin 121a is connected to a connection detection circuit 123. From the logical state of the signal pin 121a, the connection detection circuit 123 detects a first state in which the connector 121 of the control unit 12 is connected to the motherboard 11. The connection detection circuit 123 is formed of an inverter 123a as a first logic circuit. The input of the inverter 123a is connected to the signal pin 121a. In the first state, the signal level of the signal pin 121a is low, since the signal pin 121a is connected to the ground pin 111a of the connector 111. In the first embodiment, the logical state (logical value) assumed when the signal level is low is defined as logic “0”, and that assumed when the signal level is high is defined as logic “1”. Accordingly, the logical state of the input of the inverter 123a is logic “0” in the first state. In accordance with the logical state of the input, the inverter 123a outputs a detection signal (first detection signal) 124 acquired by inverting the logical state. The detection signal 124 assumes a first logical state, e.g., logic “1”, indicating the detection of the first state when the connector 121 is connected to the motherboard 11. In contrast, the detection signal 124 assumes a second logical state, e.g., logic “0”, which differs from the first logical state, when the connector 121 is disconnected from the motherboard 11.

The connector 122 of the control unit 12 includes signal pins 122a, 122b and 122c. The signal pin 122a receives a detection signal 134 from an inverter 133a, described later, incorporated in the expansion unit 13, when a third state in which the connector 122 of the control unit 12 is connected to the expansion unit 13 is assumed. The detection signal 134 assumes a particular logical state, e.g., logic “1”, when a second state in which the expansion unit 13 is connected to the motherboard 11 is assumed.

The connector 131 of the expansion unit 13 includes signal pins 131a, 131b and 131c. In the third state, the signal pins 131a, 131b and 131c are connected to the signal pins 122a, 122b and 122c of the connector 122 of the control unit 12, respectively.

In the first state, the signal pins 122b and 122c of the connector 122 of the control unit 12 are connected to the power supply pin 111b and ground pin 111c of the connector 111 of the motherboard 11 via the signal pins 121b and 121c of the connector 121 of the control unit 12, respectively. Further, in the second state, the signal pins 131b and 131c of the connector 131 of the expansion unit 13 are connected to the power supply pin 112b and ground pin 112c of the connector 112 of the motherboard 11 via the connector section 20, respectively.

The expansion unit 13 includes a connection detection circuit 133 similar to the connection detection circuit 123. The connection detection circuit 133 detects the second state in which the expansion unit 13 is connected to the motherboard 11. The connection detection circuit 133 is formed of an inverter 133a. The input of the inverter 133a is connected to the ground pin 112a of the connector 112 of the motherboard 11 via the connector section 20. Accordingly, in the second state, the signal level (logical state) of the input of the inverter 133 is low (assumes logic “0”). In accordance with the logical state of the input, the inverter 133a outputs, to the signal pin 131a, the detection signal 134 acquired by inverting the logical state. In the first embodiment, the input of the inverter 133a is pulled up via a pull-up resistor 135.

In the control unit 12, the signal pin 122a of the connector 122 is connected to a reset-releasing circuit 125, along with the output of the inverter 123a. The reset-releasing circuit 125 releases the reset state of the control unit 12 upon detection of the first state indicated by the detection signal 124 output from the inverter 123a. However, in the following case, the reset-releasing circuit 125 does not release the reset state of the control unit 12 even if the first state is detected:

In the third state in which the connector 122 of the control unit 12 is connected to the expansion unit 13, the reset-releasing circuit 125 receives the detection signal 134 from the inverter 133a of the expansion unit 13 via the signal pin 122a of the connector 122. When the logical state of the signal pin 122a is logic “0” that does not indicate the second state, the reset-releasing circuit 125 does not release the reset state of the control unit 12 regardless of whether the detection signal 124 indicating the detection of the first state is output from the inverter 123a (i.e., the first state is detected by the connection detection circuit 123).

The reset-releasing circuit 125 comprises, for example, a 2-input AND gate (second logic circuit) 125a. The respective two inputs of the AND gate 125a are connected to the output of the inverter 123a and the signal pin 122a. The respective two inputs of the AND gate 125a are pulled up by the pull-up resistors (state-setting units) 126a and 126b. The AND gate 125a outputs a reset-releasing signal/RESET of logic “1” only if the detection signal 124 output from the inverter 123a assumes logic “1” (first logical state), and the logical state of the signal pin 122a is logic “1” (particular logical state). The reset-releasing signal/RESET of logic “1” is used to release the reset state of a CPU 127 for executing telephone exchange processing.

In the work for the function extension of the control unit 12, suppose that the connectors 121 and 122 of the control unit 12 are connected to the motherboard 11 and expansion unit 13, respectively, but that the connection of the expansion unit 13 to the motherboard 11 has failed. In this incomplete connection state (first connection state), the detection signal 124 output from the inverter 123a of the control unit 12 assumes logic “1”, whereas the detection signal 134 output from the inverter 133a of the expansion unit 13 assumes logic “0”. The detection signal 134 of logic “0” is sent to the signal pin 122a of the connector 122 of the control unit 12 via the signal pin 131a of the connector 131 of the expansion unit 13. As a result, the signal pin 122a assumes logic “0”. At this time, the output of the effective reset-releasing signal/RESET of logic “1” from the AND gate 125a is prevented. Namely, the CPU 127 is prevented from being operable in an incomplete connection state.

As described above, in the above-mentioned incomplete connection state, the CPU 127 is prevented from being released from its reset state. Namely, even in the first or third state, if the second state is not established, i.e., if the signal pin 122a assumes logic “0”, it is determined that the work for the function extension of the control unit 12 is not completed, thereby preventing the CPU 127 (control unit 12) from being released from its reset state.

A description will now be given of the case where the connector 121 of the control unit 12 is connected to the motherboard 11, the connector 122 of the control unit 12 is connected to the expansion unit 13, and the expansion unit 13 is connected to the motherboard 11. In this complete connection state, the detection signal 124 and signal pin 122a assume logic “1”. At this time, the AND gate 125a outputs the effective reset-releasing signal/RESET of logic “1”, thereby releasing the reset state of the CPU 127 (control unit 12). Namely, in the first embodiment, when the first to third states are simultaneously established, it is determined that the work for the function extension of the control unit 12 is completed, thereby releasing the reset state of the CPU 127. As a result, the worker can further accurately determine, than in the prior art, the completion of the work for the function extension of the control unit 12.

After the reset state is released, the CPU 127 executes telephone exchange processing. At this time, the CPU 127 can extend its functionality by utilizing the expansion unit 13. Specifically, in the first embodiment, the CPU 127 can increase the number of ports to support from 192 to 672, for example.

A description will be given of the case where the first state is established, the second state is not established, and the third state is not established. In this case, the signal pin 122a is disconnected from the signal pin 131a of the connector 131 of the expansion unit 13. Accordingly, the detection signal 134 output from the inverter 133a of the expansion unit 13 is not sent to the signal pin 122a. The input of the AND gate 125a connected to the signal pin 122a is pulled up via the resistor 126b. Therefore, when the detection signal 134 output from the inverter 133a of the expansion unit 13 is not sent to the signal pin 122a, the input (signal pin 122a) of the AND gate 125a assumes a state of logic “1”. Further, in the first state, the detection signal 124 assumes logic “1”. At this time, the AND gate 125a outputs the effective reset-releasing signal/RESET of logic “1”. Thus, when the first state is established, the second state is not established, and the third state is not established, it is determined that the control unit 12 is used singly, disconnected from the expansion unit 13, whereby the reset state of the CPU 127 of the control unit 12 is released.

### SECOND EMBODIMENT

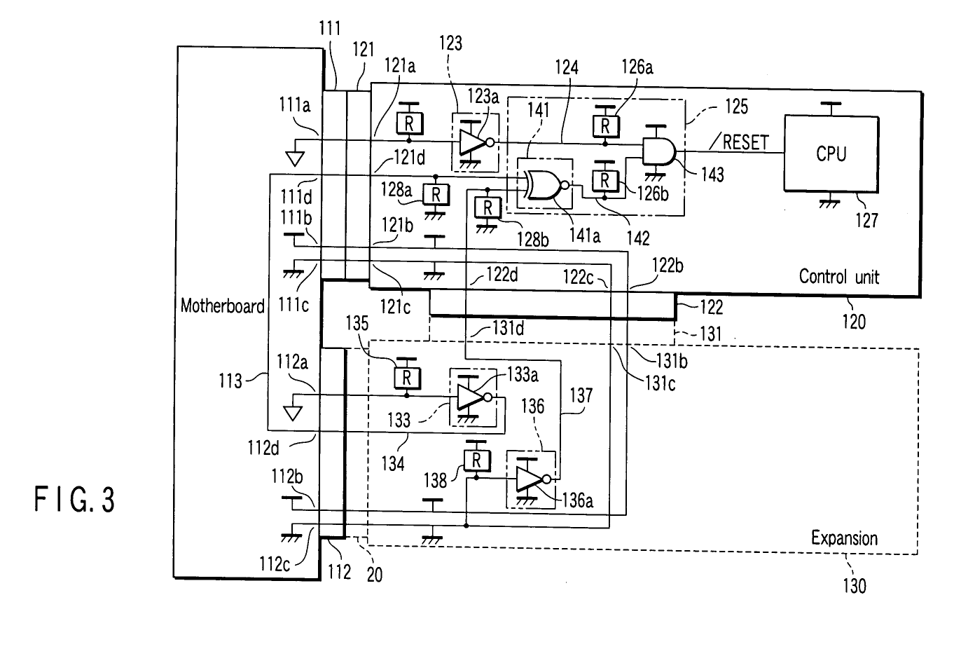

FIG. 3 shows an exemplary configuration of the essential part of a private branch exchange according to a second embodiment of the invention. In FIG. 3, elements similar to those of FIG. 1 are denoted by corresponding reference numbers. In the first embodiment, in an incomplete connection state (first connection state) in which the first and third states are simultaneously established, but the second state is not established, the CPU 127 is prevented from being released from its reset state. However, in the first embodiment, even if the first state is established and the third state is not established, not only the detection signal 124 but also the signal pin 122a assume logic “1”, regardless of whether the second state is established. Accordingly, in the first embodiment, in an incomplete connection state (second connection state) in which the first and second states are simultaneously established, but the third state is not established, the reset state of the CPU 127 is released.

The second embodiment is characterized in that in the second connection state in which the first and second states are simultaneously established, but the third state is not established, the CPU 127 is prevented from being released from its reset state, as in the first connection state in which the first and third states are simultaneously established, but the second state is not established.

Specifically, as shown in FIG. 3, the second embodiment employs a control unit 120 and expansion unit 130 that correspond to the control unit 12 and expansion unit 13 in the first embodiment, respectively. The control unit 120 includes connectors 121 and 122 like the control unit 12, and the expansion unit 130 includes a connector 131 and connection section 20 like the expansion unit 13.

Like the control unit 12, the control unit 120 is connected to the motherboard 11 and expansion unit 130. Further, like the expansion unit 13, the expansion unit 130 is connected to the motherboard 11. In FIG. 2, if necessary, the control unit 12 and expansion unit 13 may be replaced with the control unit 120 and expansion unit 130, respectively. Further, in each of the first to third states, the control unit 12 and expansion unit 13 may be replaced with the control unit 120 and expansion unit 130, respectively. Namely, in the second embodiment, the state in which the connector 121 of the control unit 120 is connected to the motherboard 11 is called a first state, the state in which the expansion unit 130 is connected to the motherboard 11 is called a second state, and the state in which the connector 122 of the control unit 120 is connected to the expansion unit 130 is called a third state.

In the second state, the detection signal 134 output from the inverter 133a of the expansion unit 130 is sent to a signal pin 112d incorporated in the connector 112 of the motherboard 11 via the connector section 20, which differs from the first embodiment. The signal pin 112d is connected to a signal pin 111d incorporated in the connector 111 of the motherboard 11 via, for example, a spare signal line 113 on the motherboard 11. In the first state, the signal pin 111d is connected to a signal pin 121d incorporated in the connector 121 of the control unit 120. In the second embodiment, the signal pins 111d and 112d are spare pins beforehand connected to the signal line 113.

The expansion unit 130 includes a connection detection circuit 136 which detects the third state. The connection detection circuit 136 is formed of an inverter 136a. The input of the inverter 136a is connected to the signal pin 131c of the expansion unit 130. In the third state, the signal pin 131c is connected to the signal pin 122c of the connector 122 of the control unit 120. In the first state, the signal pin 122c is connected to the ground pin 111c of the connector 111 of the motherboard 11. In the second state, the signal pin 131c is also connected to the ground pin 112c of the connector 112 of the motherboard 11. The inverter 136a outputs a detection signal 137 of logic “1” to the signal pin 131d of the connector 131 when the signal pin 131c assumes logic “0”. In the third state, the detection signal 137 is sent to a signal pin 122d incorporated in the connector 122 of the control unit 120.

The signal pin 131c assumes the state of logic “0” at least when the first and third states are simultaneously established, or when the second state is established. In this case, the inverter 136a outputs a detection signal 137 of logic “1”. However, when the third state is not established, the detection signal 137 is not sent to the signal pin 122d of the connector 122. It is in the third state that the detection signal 137 is sent to the signal pin 122d of the connector 122 to set the signal pin 122d to logic “1”. From this, the control unit 120 recognizes the detection signal 137 as a signal indicating whether the third state is detected.

The reset-releasing circuit 125 of the control unit 120 includes a particular-state detection circuit 141, which differs from the first embodiment. The particular-state detection circuit 141 detects a particular state in which the logical state of the signal pin 121d indicates the second state, and the logical state of the signal pin 122d indicates the third state, or in which the logical state of the signal pin 121d does not indicate the second state, and the logical state of the signal pin 122d does not indicate the third state. Upon the detection of the first state by the connection detection circuit 123, or upon the detection of the particular state by the particular-state detection circuit 141, the reset-releasing circuit 125 releases the reset state of the control unit 120 (CPU 127).

The signal level of the signal pin 121d is pulled down via a pull-down resistor (first-state-setting unit) 128a, and the signal level of the signal pin 122d is pulled down via a pull-down resistor (second-state-setting unit) 128b. As a result, the signal pin 121d assumes a logical state (logic “0”) different from the logical state (logic “1”) of the detection signal 134 indicating the detection of the second state, when the motherboard 11 is connected to the connector 121 of the control unit 120, but not to the expansion unit 130. Similarly, the signal pin 122d assumes a logical state (logic “0”) different from the logical state (logic “1”) of the detection signal 137 indicating the detection of the third state, when the motherboard 11 is connected to the connector 121 of the control unit 120, and the connector 122 of the control unit 120 is disconnected from the expansion unit 130. Namely, where the detection signal 134 output from the inverter 133a of the expansion unit 130 is not sent to the signal pin 121d of the connector 121 via the motherboard 11, the signal pin 121d is set to logic “0” via the pull-down resistor 128a. Similarly, where the detection signal 137 output from the inverter 136a of the expansion unit 130 is not sent to the signal pin 122d of the connector 122, the signal pin 122d is set to logic “0” via the pull-down resistor 128b.

The particular-state detection circuit 141 is formed of a 2-input exclusive-OR circuit 141a as a second logic circuit. The two inputs of the exclusive-OR circuit 141a are connected to the signal pins 121d and 122d. The exclusive-OR circuit 141a outputs a detection signal (second detection signal) 142 of logic “1” indicating the detection of the particular state (third logical state), when the signal pin 121d assumes logic “1” indicating the second state, and the signal pin 122d assumes logic “1” indicating the third state. The exclusive-OR circuit 141a outputs the detection signal (second detection signal) 142 of logic “1”, also when the signal pin 121d assumes logic “0” indicating no second state, and the signal pin 122d assumes logic “0” indicating no third state. In the states other than the above, the exclusive-OR circuit 141a outputs a detection signal 142 of logic “0” (indicating a fourth logical state different from the third one).

The reset-releasing circuit 125 also includes a 2-input AND gate (third logic circuit) 143 corresponding to the AND gate 125a in FIG. 1. The two inputs of the AND gate 143 receive the detection signals 124 and 142 from the inverter 123a and exclusive-OR circuit 141a, respectively. Like the AND gate 125a, the two inputs of the AND gates 143 are pulled up via the pull-up resistors (state-setting units) 126a and 126b. The AND gate 143 outputs a reset-releasing signal/RESET of logic “1” only if the output (detection signal 124) of the inverter 123a assumes logic “1” (first logical state) indicating the detection of the first state, and the output (detection signal 142) of the exclusive-OR circuit 141a assumes logic “1” (third logical state) indicating the detection of the particular logical state.

Suppose here that during the work for the function extension of the control unit 12, the motherboard 11 is connected to the connector 121 of the control unit 120 and the expansion unit 130, but the connector 122 of the control unit 120 is disconnected from the expansion unit 130. In this incomplete connection state (second connection state), the output (detection signal 124) of the inverter 123a assumes logic “1”. Further, the signal pin 121d of the connector 121 assumes logic “1”, and the signal pin 122d of the connector 122 assumes logic “0”. In this case, the output (detection signal 142) of the exclusive-OR circuit 141a assumes logic “1”, thereby preventing the AND gate 125a from outputting the effective reset-releasing signal /RESET of logic “1”. As a result, the CPU 127 is prevented from being operable in the incomplete connection state that cannot be prevented in the first embodiment, i.e., the second connection state (in which the first and second states are established, and the third state is not established).

In the first and second embodiments, it is assumed that the invention is applied to the control unit of an in-plane exchange. However, the invention is also applicable to a control unit for information processing apparatuses other than in-plane exchanges. It is sufficient if the control unit is used connected to a motherboard, and can extend its functionality when it is connected to an expansion unit.

While certain embodiments of the inventions have been described, these embodiments have been presented by way of example only, and are not intended to limit the scope of the inventions. Indeed, the novel apparatuses and methods described herein may be embodied in a variety of other forms; furthermore, various omissions, substitutions and changes in the form of the apparatuses and methods described herein may be made without departing from spirit of the inventions. The accompanying claims and their equivalents are intended to cover such forms or modifications as would fall within the scope and sprit of the inventions.

What is claimed is:

1. A control unit permitted to be connected to a motherboard, and permitted to extend functionality thereof when the control unit is connected to an expansion unit, comprising:
a first connector to be connected to the motherboard;
a connection detection circuit which detects a first state in which the first connector is connected to the motherboard;
a second connector to be connected to the expansion unit and including a particular signal pin, the particular signal pin receiving, from the expansion unit, a particular signal which assumes a particular logical state in a second state in which the expansion unit is connected to the motherboard;
a state-setting unit which sets the particular signal pin to the particular logical state when the particular signal is not sent to the particular signal pin; and
a reset-releasing circuit which releases a reset state of the control unit upon detection of the first state by the connection detection circuit, the reset-releasing circuit preventing the reset state of the control unit from being released regardless of whether the connection detection circuit detects the first state, when the particular signal pin assumes a logical state different from the particular logical state.

2. The control unit according to claim 1, wherein:
the connection detection circuit includes a first logic circuit which outputs a detection signal, the detection signal assuming a first logical state indicative of detection of the first state when the first connector is connected to the motherboard, the detection signal assuming a second logical state different from the first logical state when the first connector is disconnected from the motherboard; and
the reset-releasing circuit includes a second logic circuit which outputs a reset-releasing signal used to release the reset state of the control unit based on a logical state of the detection signal and a logical state of the particular signal pin, the second logic circuit outputting the reset-releasing signal when the detection signal is in the first logical state and the particular signal pin is in the particular logical state, the second logic circuit preventing the reset-releasing signal from being output when the particular signal pin is in a logical state other than the particular logical state.

3. The control unit according to claim 1, further comprising a CPU permitted to operate when the reset state of the control unit is released by the reset-releasing circuit, thereby executing telephone exchange processing.

4. A control unit permitted to be connected to a motherboard, and permitted to extend functionality thereof when the control unit is connected to an expansion unit, comprising:
a first connector to be connected to the motherboard and including a first signal pin, the first signal pin receiving, from the expansion unit via the motherboard, a first signal which assumes a particular logical state in a second state in which the expansion unit is connected to the motherboard;
a connection detection circuit which detects a first state in which the first connector is connected to the motherboard;
a second connector to be connected to the expansion unit and including a second signal pin, the second signal pin receiving, from the expansion unit, a second signal which assumes another particular logical state in a third state in which the expansion unit is connected to the motherboard;
a particular-state detection unit which detects a particular state in which a logical state of the first signal pin indicates the second state and a logical state of the second signal pin indicates the third state, or in which the logical state of the first signal pin does not indicate the second state and the logical state of the second signal pin does not indicate the third state; and
a reset-releasing circuit which releases a reset state of the control unit upon detection of the first state by the connection detection circuit, and upon detection of the particular state by the particular-state detection circuit.

5. The control unit according to claim 4, wherein the reset-releasing circuit does not release the reset state of the control unit when the connection detection circuit detects the first state, and the particular-state detection circuit does not detect the particular state.

6. The control unit according to claim 5, wherein:
the connection detection circuit includes a first logic circuit which outputs a first detection signal, the first detection signal assuming a first logical state indicative of detection of the first state when the first connector is connected to the motherboard, the first detection signal assuming a second logical state different from the first logical state when the first connector is disconnected from the motherboard;
the particular-state detection circuit includes a second logic circuit which outputs a second detection signal, the second detection signal assuming a third logical state indicative of detection of the particular state in a first case where the logical state of the first signal pin indicates the second state and the logical state of the second signal pin indicates the third state, or in a second case where the logical state of the first signal pin does not indicate the second state and the logical state of the second signal pin does not indicate the third state, the second detection signal assuming a fourth logical state different from the third logical state in cases other than the first and second cases.
the reset-releasing circuit includes a third logic circuit which outputs a reset-releasing signal used to release the reset state of the control unit, based on the first and second detection signals, the third logic circuit outputting the reset-releasing signal when the first and second detection signals assume the first and third logical states, respectively, the third logic circuit outputting no reset-releasing signal except when the first and second detection signals assume the first and third logical states, respectively.

7. The control unit according to claim 6, further comprising:
a first-state-setting unit which sets the first signal pin in the second logical state when the first signal is not sent to the first signal pin; and
a second-state-setting unit which sets the second signal pin in the fourth logical state when the second signal is not sent to the second signal pin.

8. The control unit according to claim 4, further comprising a CPU permitted to operate when the reset state of the control unit is released by the reset-releasing circuit, thereby executing telephone exchange processing.
